(19) United States
(12) Patent Application Publication
(10) Pub. No.: US 2025/0234444 A1
(43) Pub. Date: Jul. 17, 2025

(54) EXTREME ULTRAVIOLET LIGHT GENERATION SYSTEM AND ELECTRONIC DEVICE MANUFACTURING METHOD

(71) Applicant: Gigaphoton Inc., Tochigi (JP)

(72) Inventors: Shogo KITASAKA, Oyama-shi (JP); Yuichi NISHIMURA, Oyama-shi (JP)

(73) Assignee: Gigaphoton Inc., Tochigi (JP)

(21) Appl. No.: 18/969,886

(22) Filed: Dec. 5, 2024

(30) Foreign Application Priority Data
Jan. 12, 2024 (JP) 2024-003261

(51) Int. Cl. H05G 2/00; G03F 1/66; G03F 7/00

(52) U.S. Cl. CPC H05G 2/0027; G03F 1/66; G03F 7/70033; H05G 2/0023; H05G 2/0035

(57) ABSTRACT

An extreme ultraviolet light generation system, generating extreme ultraviolet light by irradiating a target substance with laser light, includes a tank storing the target substance in a liquid state, a nozzle outputting the target substance stored in the tank, a piezoelectric element applying vibration to the target substance to be output from the nozzle to generate droplets of the target substance, a droplet detection device detecting a time interval of passage of the droplets output from the nozzle, and at least one processor. The processor acquires a first value of a vibration parameter relating to the vibration of the piezoelectric element, acquires a variation of the time interval corresponding to each of a plurality of values including the first value of the vibration parameter, and generates the droplets using a second value with which the variation of the time interval is smaller than that with the first value.

### CROSS-REFERENCE TO RELATED APPLICATIONS

The present application claims the benefit of Japanese Patent Application No. 2024-003261, filed on Jan. 12, 2024, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system. As the EUV light generation apparatus, a laser produced plasma (LPP) type apparatus using plasma generated by irradiating a target substance with laser light has been developed.

### LIST OF DOCUMENTS

### Patent Documents

Patent Document 1: U.S. Pat. No. 10,225,917
Patent Document 2: U.S. Pat. No. 10,386,287

### SUMMARY

An extreme ultraviolet light generation system according to an aspect of the present disclosure is an extreme ultraviolet light generation system configured to generate extreme ultraviolet light by irradiating a target substance with laser light. The system includes a tank configured to store the target substance in a liquid state, a nozzle configured to output the target substance stored in the tank, a piezoelectric element configured to apply vibration to the target substance to be output from the nozzle to generate droplets of the target substance, a droplet detection device configured to detect a time interval of passage of the droplets output from the nozzle, and at least one processor. The processor acquires a first value of a vibration parameter relating to the vibration of the piezoelectric element, acquires a variation of the time interval corresponding to each of a plurality of values including the first value of the vibration parameter, and generates the droplets using a second value with which the variation of the time interval is smaller than that with the first value.

An electronic device manufacturing method according to an aspect of the present disclosure includes generating extreme ultraviolet light using an extreme ultraviolet light generation system by irradiating a target substance with laser light, outputting the extreme ultraviolet light to an exposure apparatus, and exposing a photosensitive substrate to the extreme ultraviolet light in the exposure apparatus to manufacture an electronic device. The extreme ultraviolet light generation system includes a tank configured to store the target substance in a liquid state, a nozzle configured to output the target substance stored in the tank, a piezoelectric element configured to apply vibration to the target substance to be output from the nozzle to generate droplets of the target substance, a droplet detection device configured to detect a time interval of passage of the droplets output from the nozzle, and at least one processor. The processor acquires a first value as a vibration parameter relating to vibration of the piezoelectric element, acquires a variation of the time interval corresponding to each of a plurality of values including the first value as the vibration parameter, and generates the droplets using a second value with which the variation of the time interval is smaller than that with the first value.

An electronic device manufacturing method according to an aspect of the present disclosure includes generating extreme ultraviolet light using an extreme ultraviolet light generation system by irradiating a target substance with laser light, inspecting a defect of a reticle by irradiating the reticle with the extreme ultraviolet light, selecting a reticle using a result of the inspection, and exposing and transferring a pattern formed on the selected reticle onto a photosensitive substrate. The extreme ultraviolet light generation system includes a tank configured to store the target substance in a liquid state, a nozzle configured to output the target substance stored in the tank, a piezoelectric element configured to apply vibration to the target substance to be output from the nozzle to generate droplets of the target substance, a droplet detection device configured to detect a time interval of passage of the droplets output from the nozzle, and at least one processor. The processor acquires a first value as a vibration parameter relating to vibration of the piezoelectric element, acquires a variation of the time interval corresponding to each of a plurality of values including the first value as the vibration parameter, and generates the droplets using a second value with which the variation of the time interval is smaller than that with the first value.

### BRIEF DESCRIPTION OF THE DRAWINGS

Embodiments of the present disclosure will be described below merely as examples with reference to the accompanying drawings.

FIG. 1 is a schematic diagram showing the configuration for measuring a droplet passage interval.

FIG. 2 is a schematic diagram of an output signal of a light receiving element of a droplet detection sensor.

FIG. 3 is a diagram showing an example of a voltage waveform to be applied to a piezoelectric element.

FIG. 4 is a diagram schematically showing a configuration example of an EUV light generation system according to a comparative example.

FIG. 5 is a flowchart showing main flow of operation of the EUV light generation system.

FIG. 6 is a flowchart showing an example of a DL combining adjustment subroutine.

FIG. 7 is a graph showing an example of the combining failure rate measured in the DL combining adjustment.

FIG. 8 is a flowchart showing an example of a DL combining control subroutine.

FIG. 9 is a diagram for explaining an operational Duty value set by the DL combining control.

FIG. 10 is a flowchart showing an example of the DL combining adjustment subroutine according to a first embodiment.

FIG. 11 is a graph showing an example of characteristic data indicating the relationship between a DL passage interval σ and a Duty acquired in the DL combining adjustment.

FIG. 12 is a flowchart showing an example of the DL combining control subroutine according to the first embodiment.

FIG. 13 is a graph for explaining the process of changing the Duty in a performance improving direction.

FIG. 14 is a graph showing an example of change in the DL passage interval σ and the Duty with respect to the control time in the DL combining control according to the first embodiment.

FIG. 15 is a graph showing correlations between the DL passage interval σ and the EUV energy stability.

FIG. 16 is a graph showing correlations between the DL passage interval σ and the EUV light emission cycle.

FIG. 17 is a table showing the relationship among the DL passage interval σ, the EUV energy stability, and the EUV light emission cycle stability in numerical values.

FIG. 18 is a flowchart showing an example of the DL combining control subroutine according of a modification of the first embodiment.

FIG. 19 is a diagram schematically showing an exemplary configuration of the EUV light generation system according to a second embodiment.

FIG. 20 is a flowchart showing an example of the DL combining control subroutine according to the second embodiment.

FIG. 21 is a diagram schematically showing an exemplary configuration of the EUV light generation system according to a third embodiment.

FIG. 22 is a flowchart showing an example of the DL combining control subroutine according to the third embodiment.

FIG. 23 is a diagram schematically showing the configuration of an exposure apparatus connected to the EUV light generation system.

FIG. 24 is a diagram schematically showing the configuration of an inspection apparatus connected to the EUV light generation system.

### DESCRIPTION OF EMBODIMENTS

### <Contents>

1. Description of terms
1.1 Combining failure rate
1.2 Duty
   2. Outline of EUV light generation system according to comparative example
2.1 Configuration
2.2 Operation
   2.2.1 Example of DL combining adjustment
   2.2.2 Example of DL combining control
2.3 Problem

### 3. First Embodiment

3.1 Configuration
3.2 Operation
   3.2.1 Example of DL combining adjustment
   3.2.2 Example of DL combining control
3.3 Effect
3.4 Modification

### 4. Second Embodiment

4.1 Configuration
4.2 Operation
4.3 Effect

### 5. Third Embodiment

5.1 Configuration
5.2 Operation
5.3 Effect
   6. Electronic device manufacturing method

### 7. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

### 1.1 Combining Failure Rate

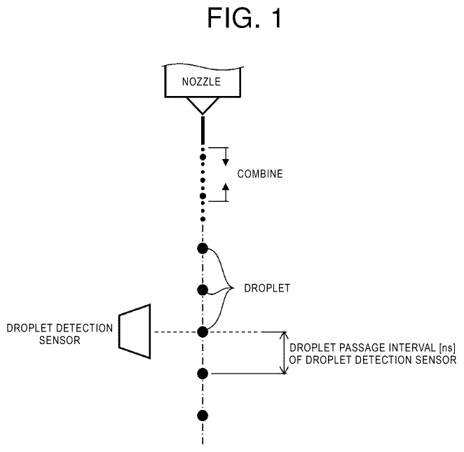

FIG. 1 is a schematic diagram showing the configuration for measuring a droplet passage interval being a time interval of droplet passage. FIG. 1 shows a nozzle that ejects a target substance, droplets formed by the target substances ejected from the nozzle, and a droplet detection sensor being a timing sensor that detects a timing at which the droplet passes. The droplet detection sensor is arranged facing a position through which the droplet passes. The droplet detection sensor includes a light receiving element (not shown), and detects a change in the voltage of the light receiving element caused by passage of the droplet. A light emission trigger detection threshold for light emission trigger of a pulse laser device is set for the voltage of the light receiving element.

A “droplet” is a form of a target supplied into a chamber. The droplet may refer to a droplet-shaped target having a substantially spherical shape due to surface tension of a molten target substance. In the present specification and drawings, the expression “DL” is an abbreviation of a “droplet.”

A jet of the target substance ejected from the nozzle is separated into droplet forms, which are combined to form the DL. The normally-output DL obtained by combining a specified number of droplets creates a relatively large shadow. Therefore, when the normally-output DL passes beside the droplet detection sensor, the voltage of the light receiving element is greatly reduced. As a result, the voltage of the light receiving element falls below the light emission trigger detection threshold, causing a trigger start point of the pulse laser device.

On the other hand, depending on DL generation conditions, the DL having insufficient combining number and the DL having no combining occur. Although the shadow due to the DL with combining failure is small and the voltage drop of the light receiving element is small, the voltage of the light receiving element may fall below the light emission trigger detection threshold to cause the trigger start point of the pulse laser device.

In order to avoid such an event, the DL generation conditions are determined using, as an index, the detection interval (DL passage interval [ns]) from when the voltage of the light receiving element falls below the light emission trigger detection threshold until when the voltage of the light receiving element next falls below the light emission trigger detection threshold. That is, an allowable range is set for the DL passage interval, and it is determined whether or not the DL passage interval is within the allowable range.

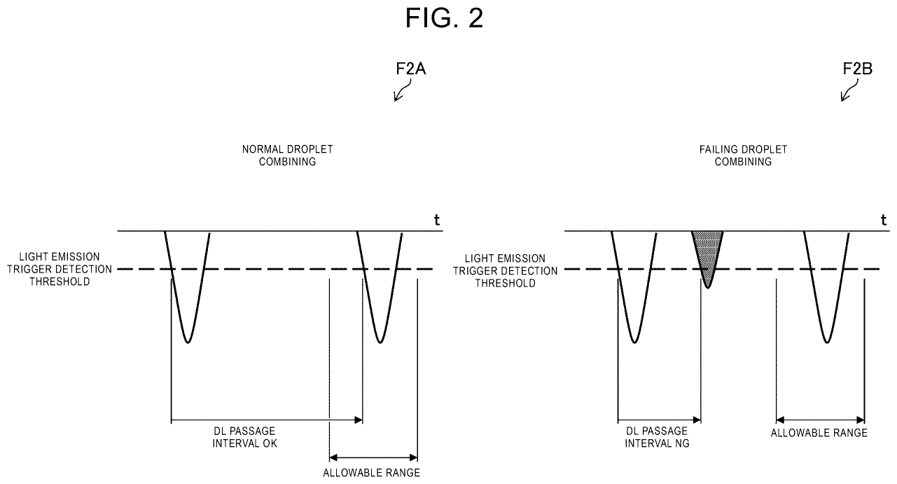

FIG. 2 is a schematic diagram of an output signal (passage timing signal) of the light receiving element of the droplet detection sensor. In FIG. 2, the horizontal axis represents time, and the vertical axis represents, for example, a voltage. F2A of FIG. 2 shows a case in which the DL passage interval is within the allowable range. Further, F2B of FIG. 2 shows a case in which the DL passage interval is out of the allowable range. The “combining failure rate” is calculated by the following expression 1.

$$Combining failure rate [ \% ] = ( number of DL whose DL passage interval is out of the allowable range / number of DL samples ) \times 100 \qquad ( Expression 1 )$$

### 1.2 Duty

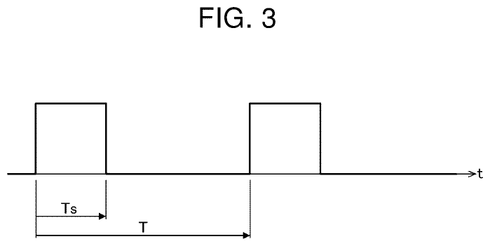

FIG. 3 is a diagram showing an example of a voltage waveform to be applied to the piezoelectric element for generating a droplet. FIG. 3 shows an example of a rectangular wave having a predetermined cycle. In FIG. 3, the horizontal axis represents time, and the vertical axis represents the voltage. “Duty” is a ratio [%] of an on time (high potential voltage time) Ts in one rectangular wave cycle T.

### 2. Outline of EUV Light Generation System According to Comparative Example

### 2.1 Configuration

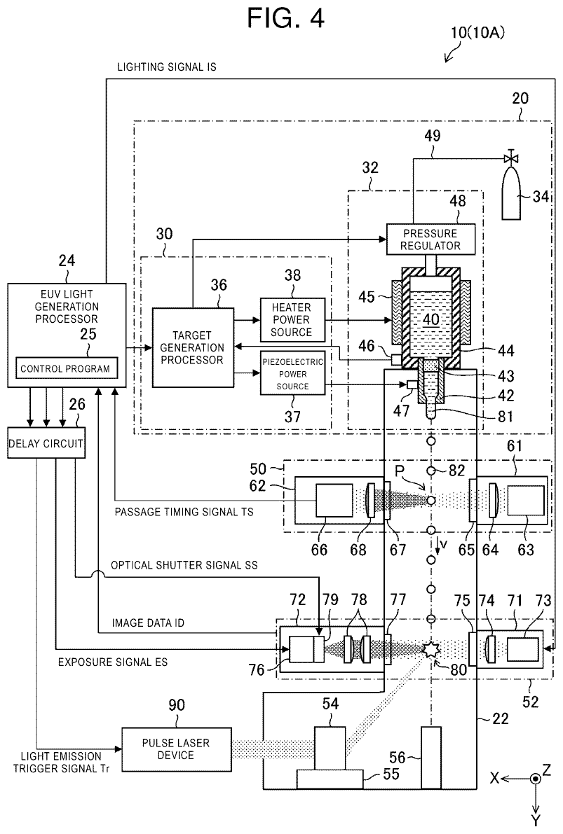

FIG. 4 is a diagram schematically showing a configuration example of an extreme ultraviolet light generation system 10 (hereinafter, referred to as the EUV light generation system 10) according to a comparative example. The comparative example of the present disclosure is an example recognized by the applicant as known only by the applicant, and is not a publicly known example admitted by the applicant. The expression “EUV light” is an abbreviation for “extreme ultraviolet light.”

The EUV light generation system 10 includes a target generation system 20, a chamber 22, an EUV light generation processor 24 including a control program 25, a delay circuit 26, and a pulse laser device 90. The target generation system 20 includes a target control system 30, a target supply unit 32, and an inert gas supply unit 34. The target control system 30 includes a target generation processor 36, a piezoelectric power source 37, and a heater power source 38.

The processor in the present disclosure is a processing device including a storage device in which the control program is stored and a central processing unit (CPU) that executes the control program. The processor is specifically configured or programmed to perform various processes included in the present disclosure. Although the EUV light generation processor 24 and the target generation processor 36 are separate from each other, the EUV light generation processor 24 and the target generation processor 36 may be configured as a single processor. In that case, the single processor may perform the operation of the EUV light generation processor 24 and the operation of the target generation processor 36.

The target supply unit 32 includes a nozzle 42 having a hole for outputting a molten target substance 40, a filter 43, a tank 44 for storing the target substance 40, a heater 45, a temperature sensor 46, a piezoelectric element 47, and a pressure regulator 48.

The nozzle 42 corresponds to the nozzle shown in FIG. 1. The filter 43 is arranged upstream of the nozzle 42 and removes impurities contained in the target substance 40. The target substance 40 is, for example, tin (Sn). The nozzle 42, the heater 45, and the temperature sensor 46 are fixed to the tank 44. The piezoelectric element 47 is fixed to the nozzle 42.

The pressure regulator 48 is arranged at a pipe 49 between the inert gas supply unit 34 and the tank 44. An inert gas supplied from the inert gas supply unit 34 may be, for example, an Ar gas or an He gas.

The target substance 40 in the tank 44 is output as a jet 81 from the nozzle 42 owing to the pressure difference between the pressure of the inert gas supplied from the pressure regulator 48 and the pressure in the chamber 22. When vibration is applied to the nozzle 42 by the piezoelectric element 47, the jet 81 output from the nozzle 42 is separated into droplet forms to form a droplet 82 (hereinafter, referred to as the DL 82).

The chamber 22 includes a droplet detection device 50, a target image measurement device 52, a laser light concentrating optical system 54, an XY axis stage 55, and a target collection unit 56.

The droplet detection device 50 (hereinafter, referred to as the DL detection device 50) corresponds to the droplet detection sensor shown in FIG. 1. The DL detection device 50 includes a light source unit 61 and a light receiving unit 62. The light source unit 61 includes a CW laser 63 which is a light source, an illumination optical system 64 which is a light concentrating lens, and a window 65. The light source unit 61 is arranged so as to illuminate the DL 82 at a predetermined position P on a target trajectory between the nozzle 42 of the target supply unit 32 and a plasma generation region 80.

The light receiving unit 62 includes an optical sensor 66 which is a light receiving element, and a window 67 and a light receiving optical system 68 for introducing CW laser light to the optical sensor 66. The light receiving unit 62 is arranged so as to receive the CW laser light output from the light source unit 61. When the DL 82 blocks the CW laser light, the output of the optical sensor 66 varies. The light receiving unit 62 generates a passage timing signal TS to notify the timing at which the DL 82 passes the position P based on the variation, and inputs the passage timing signal TS to the EUV light generation processor 24.

The passage timing signal TS is input to the delay circuit 26 via the EUV light generation processor 24. A signal line for setting the delay time of the delay circuit 26 from the EUV light generation processor 24 may be connected to the delay circuit 26.

The delay circuit 26 outputs a light emission trigger signal Tr to the pulse laser device 90. The delay circuit 26 outputs an exposure signal ES and an optical shutter signal SS to the target image measurement device 52.

The target image measurement device 52 includes a light source unit 71 and a light receiving unit 72. The light source unit 71 includes a flash lamp 73 which is a light source, an illumination optical system 74 which is a light concentrating lens, and a window 75. The light source unit 71 is arranged to illuminate the DL 82 in the plasma generation region 80. The light source unit 71 turns on the flash lamp 73 based on a lighting signal IS input from the EUV light generation processor 24.

The light receiving unit 72 includes an image sensor 76, a window 77 that guides flash lamp light of the flash lamp 73 to the image sensor 76, a light receiving optical system 78, and an optical shutter 79. The light receiving unit 72 is arranged to receive the flash lamp light output from the light source unit 71.

The image sensor 76 has light receiving elements (not shown) arranged two-dimensionally and is, for example, a CCD (charge-coupled device) type image sensor. The light receiving unit 72 captures an image of a region including the plasma generation region 80 to generate image data ID, and inputs the image data ID to the EUV light generation processor 24.

The light receiving unit 72 starts exposure of the image sensor 76 based on the exposure signal ES input from the delay circuit 26. Further, the light receiving unit 72 opens and closes the optical shutter 79 based on the optical shutter signal SS input from the delay circuit 26. The light receiving optical system 78 forms an image of the DL 82 due to the flash lamp light output from the light source unit 71 on a light receiving surface of the image sensor 76 when the optical shutter 79 is in the open state. The image sensor 76 photoelectrically converts the image of the DL 82 formed on the light receiving surface to generate the image data ID representing the image of the DL 82, and outputs the image data ID to the EUV light generation processor 24.

The pulse laser device 90 outputs pulse laser light based on the light emission trigger signal Tr. The pulse laser device 90 may be, for example, a CO: laser device. Further, the pulse laser device 90 may be a solid-state laser device in which a crystal obtained by doping any one of YVO4 (yttrium-vanadium oxide), YLF (yttrium-lithium fluoride), and YAG (yttrium-aluminum-garnet) with an impurity is used as a laser medium.

The laser light concentrating optical system 54 is an optical system that concentrates the pulse laser light output from the pulse laser device 90 and introduced into the chamber 22 on the plasma generation region 80. The laser light concentrating optical system 54 is supported by the XY axis stage 55. The XY axis stage 55 can move the laser light concentrating optical system 54 in two axial directions of the X-axis direction and the Y-axis direction. By adjusting the position of the laser light concentrating optical system 54 by the XY axis stage 55, it is possible to adjust the concentration position of the pulse laser light. Each optical element is arranged such that the concentration position of the laser light concentrating optical system 54 substantially coincides with the plasma generation region 80.

The target collection unit 56 is arranged on the trajectory of the DL 82, and collects the DL 82 which have not been irradiated with the pulse laser light.

Further, an EUV light concentrating mirror (not shown) is arranged in the chamber 22. The EUV light concentrating mirror has a spheroidal reflection surface. A multilayer reflective film which molybdenum and silicon are alternately laminated is formed on the reflection surface of the EUV light concentrating mirror. The EUV light concentrating mirror has a first focal point and a second focal point and is positioned such that the first focal point is located in the plasma generation region 80. The EUV light concentrating mirror selectively reflects EUV light from among the radiation light that is radiated from the plasma generated at the plasma generation region 80. The EUV light concentrating mirror concentrates the selectively reflected EUV light on the second focal point (intermediate focal point). An aperture (not shown) is arranged at the intermediate focal point, and the EUV light having passed through the aperture enters an exposure apparatus or an inspection apparatus (not shown).

### 2.2 Operation

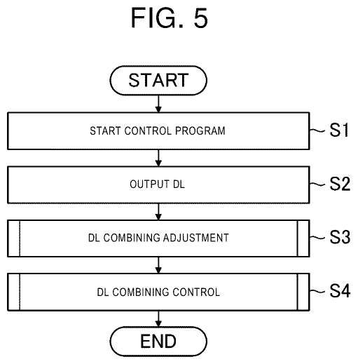

FIG. 5 is a flowchart showing main flow of operation of the EUV light generation system 10. In step S1, when the EUV light generation processor 24 starts execution of the control program 25, a target generation signal is input from the EUV light generation processor 24 to the target generation processor 36.

In step S2, the target generation processor 36 controls the heater power source 38 based on a detection value of the temperature sensor 46 so that the temperature of Sn in the target supply unit 32 becomes equal to or higher than the melting point and melts Sn stored in the tank 44 to be a liquid state. For example, the target generation processor 36 controls the heater power source 38 so that Sn in the target supply unit 32 becomes a predetermined temperature of 232° C. to 300° C. The target generation processor 36 also controls the inert gas to a predetermined pressure by the pressure regulator 48, for example, the pressure of 0.2 MPa to 40 MPa, to output the liquid Sn inside the tank 44 to the outside of the nozzle 42.

In step S3, the target generation processor 36 vibrates the nozzle 42 such that the jet 81 of the liquid Sn output from the nozzle 42 is turned into droplets and a plurality of droplets are combined to generate a combined droplet DL having a predetermined diameter at a predetermined cycle. For example, the target generation processor 36 applies a voltage waveform of a rectangular wave having a predetermined frequency and a predetermined Duty to the piezoelectric element 47 via the piezoelectric power source 37, and causes the nozzle 42 to vibrate at a predetermined frequency.

Hereinafter, the term “DL” in the case of generating a DL or generation of a DL in the present specification refers to a combined DL unless otherwise specified. In the present specification, the Duty of the voltage waveform of the rectangular wave applied to the piezoelectric element 47 is referred to as “Duty for the piezoelectric element 47” or simply “Duty.” The Duty is one of vibration parameters related to the vibration of the piezoelectric element 47, and the value of the Duty is referred to as a “Duty value.” The Duty value is an example of the “duty value” in the present disclosure.

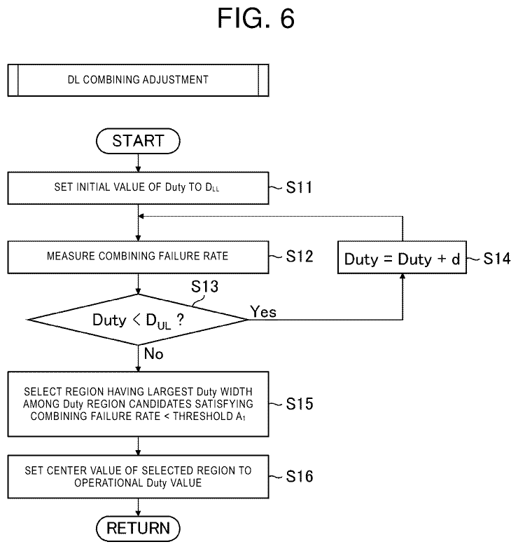

Further, in step S3, the target generation processor 36 measures the combining failure rate of DLs with respect to the Duty, and stores the Duty and the combining failure rate in association with each other. Then, the target generation processor 36 drives the piezoelectric element 47 with the rectangular wave having the Duty value having the combining failure rate smaller than a threshold. A specific example of a subroutine applied to the DL combining adjustment in step S3 will be described later with reference to FIG. 6.

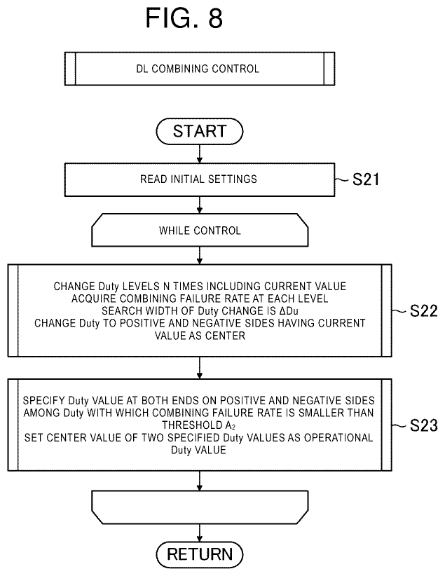

In step S4, the target generation processor 36 starts control of maintaining a DL combining state by finely adjusting the Duty for the piezoelectric element 47 using the combining failure rate of DLs as an index. Here, the DL combining control may be performed irrespective of non-irradiation (at the time of EUV light non-emission) and irradiation (at the time of EUV light emission) to DLs with the pulse laser light. A specific example of a subroutine applied to the DL combining control in step S4 will be described later with reference to FIG. 8.

### 2.2.1 Example of DL Combining Adjustment

FIG. 6 is a flowchart showing an example of the DL combining adjustment subroutine applied to step S3 in FIG. 5. The present subroutine is performed at the time of EUV light non-emission.

When the process in step S3 is started, in step S11, the target generation processor 36 sets the Duty for the piezoelectric element 47 to a lower limit value D_{LL} being an initial value. The target generation processor 36 can change the Duty in units of a step amount d in a numerical range from the lower limit value Dir to an upper limit value D_{UL}. As a typical parameter value of the Duty, the lower limit value D_{LL} may be 1%, the upper limit value D_{UL} may be 99%, and the step amount d may be 0.1%.

In step S12, the target generation processor 36 measures the combining failure rate of DLs with the set Duty value. That is, the target generation processor 36 controls the piezoelectric power source 37 so as to apply the voltage waveform of the rectangular wave having the set Duty value to the piezoelectric element 47, and drives the piezoelectric element 47 via the piezoelectric power source 37 to generate the DL 82. Further, the target generation processor 36 acquires the passage timing signal TS via the EUV light generation processor 24, measures the DL passage interval based on the passage timing signal TS, and calculates the combining failure rate with the Duty value set based on above-described expression 1. The number of DLs for each Duty value, which is the number of samples for calculating the combining failure rate, may be 10000. Then, the target generation processor 36 stores the Duty and the combining failure rate in association with each other.

In step S13, the target generation processor 36 determines whether or not the set Duty value is smaller than the upper limit value D_{UL}. When the determination result in step S13 is Yes, the target generation processor 36 proceeds to step S14, sets a new Duty value by adding the step amount d to the set Duty value, and then returns to step S12.

The loop of steps S12 to S14 is repeated until the Duty value reaches the upper limit value D_{UL}. Thus, by measuring the combining failure rate with each Duty value while increasing the Duty from the lower limit value D_{LL} to the upper limit value D_{UL} in increments of the step amount d, characteristic data indicating the relationship between the Duty and the combining failure rate can be obtained.

When the determination result in step S13 is No, the target generation processor 36 proceeds to step S15. In step S15, the target generation processor 36 selects the region having the largest Duty width among region candidates each having a consecutive Duty width with which the combining failure rate is smaller than a threshold A₁.

In step S16, the target generation processor 36 sets the center value of the region selected in step S15 to an operational Duty value. After step S16, the target generation processor 36 returns to the flowchart of FIG. 5.

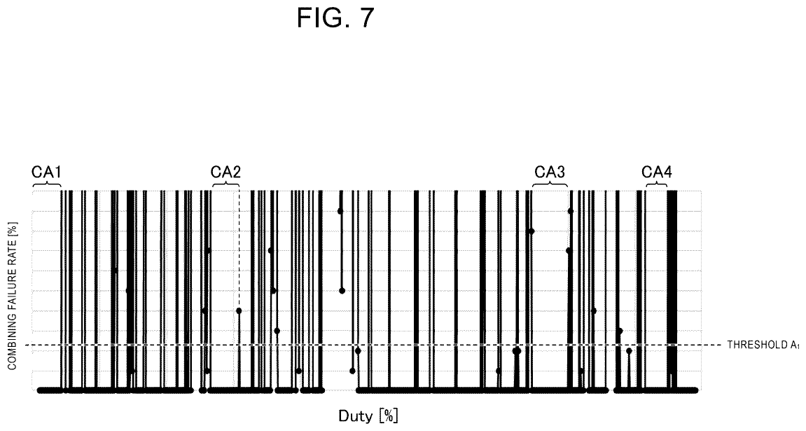

FIG. 7 is a graph showing an example of the combining failure rate measured in the DL combining adjustment. In FIG. 7, the horizontal axis represents the Duty, and the vertical axis represents the combining failure rate. FIG. 7 shows an example of the combining failure rate obtained by scanning with the Duty value being from 1% to 99% in increments of 0.1% while the irradiation of the pulse laser light is stopped.

In FIG. 7, four region candidates CA1, CA2, CA3, CA4 are regions each satisfying the condition that the consecutive Duty width with which the combining failure rate is smaller than the threshold A₁ is equal to or larger than a specified width. The region candidates CA1, CA2, CA3, CA4 are regions in the vicinity of the Duty values of 3%, 28%, 77%, and 92%, respectively. Among the region candidates, a region having the largest Duty width is selected as a maximum Duty width region. Here, the region candidate CA3 is selected as the maximum Duty width region, and the Duty value at the center of the Duty region of the region candidate CA3 is selected as a Duty value appropriate for generation of the DL 82.

### 2.2.2 Example of DL Combining Control

FIG. 8 is a flowchart showing an example of a DL combining control subroutine applied to step S4 in FIG. 5. In the present subroutine, the Duty is controlled using the combining failure rate as an index. This subroutine can be performed at both the time of EUV light non-emission and the time of EUV light emission.

When the process of step S4 is started, in step S21, the target generation processor 36 reads initial settings. The parameters to be initialized include a search width ΔDu of the Duty value for evaluating EUV performance, search levels N of the Duty, a threshold A₂ of the combining failure rate, and a number of combining failure rate calculation samples. The target generation processor 36 reads the initial set values for each of these parameters. The search width ΔDu may be 0.02%, the search levels N may be 5, the threshold A₂ may be 0.02%, and the number of combining failure rate calculation samples may be 10000.

The processes of steps S22 to S23 are repeated as long as the condition that the DL combining state needs to be maintained is satisfied. When there is no need to maintain the DL combining state in association with the stop of DL outputting by the stop command or the like from an external apparatus such as an exposure apparatus (not shown) or an operator, the target generation processor 36 ends the repetitive processes and ends the present subroutine, and returns to the flowchart of FIG. 5.

In step S22, the target generation processor 36 acquires the combination failure rates with the Duty values of the search levels N having the operational Duty value that is the set Duty value as the center. The interval between the search levels N is the search width ΔDu, and the order of the Duty value for acquiring the combining failure rates may be arbitrary.

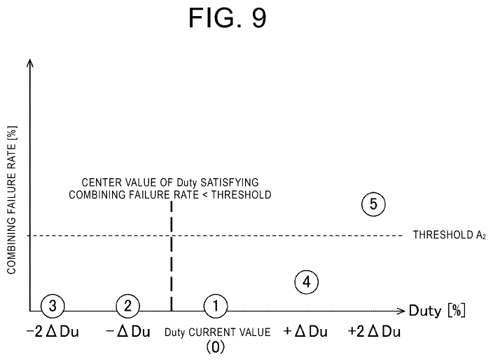

In step S23, the target generation processor 36 specifies the Duty values at both ends of the positive side and the negative side with which the combination failure rate is smaller than the threshold A₂ among the Duty values with which the combination failure rates are acquired in step S22. Further, the target generation processor 36 sets the center value (average value) of the Duty values at both ends of the positive side and the negative side as a new operational Duty value. Specific operation of step S22 and step S23 will be described with reference to FIG. 9.

After step S23, when the repetitive processes do not need to be continued by the stop command or the like as described above, the target generation processor 36 returns to the flowchart of FIG. 5.

FIG. 9 is a diagram for explaining the operational Duty value set by the DL combining control. In FIG. 9, the horizontal axis represents the Duty, and the vertical axis represents the combining failure rate [%]. Each circle in FIG. 9 represents a plot position of the combining failure rate with respect to the Duty, and a number in the circle represents a search order. In the example shown in FIG. 9, the Duty values of the search orders 1, 2, 3, 4, and 5 are “current value”, “current value−ΔDu”, “current value−ΔDu×2”, “current value+ΔDu”, and “current value+ΔDu×2”, respectively.

Here, the combining failure rates with the Duty values of the search orders 1 to 4 are each smaller than the threshold A₂, and the combining failure rate with the Duty value of the search order 5 is larger than the threshold A₂. Therefore, the target generation processor 36 specifies the Duty value of the search order 4 that is on the most positive side, that is, the largest value, among the Duty values of the search orders 1 to 4 with which the combining failure rates are smaller than the threshold A₂. Further, the target generation processor 36 specifies the Duty value of the search order 3 that is on the most negative side, that is, the smallest value, among the Duty values of the search orders 1 to 4 with which the combining failure rates are smaller than the threshold A₂. Further, the target generation processor 36 sets the center value of the two Duty values as the operational Duty value.

### 2.3 Problem

In the EUV light generation system 10 according to the comparative example, when the combining failure rate is equal to or smaller than the threshold, the Duty cannot be improved more, and therefore, variation in the DL passage interval caused by variation in the velocity of DLs cannot be made equal to or smaller than a certain level, and thus EUV energy stability 30 is not improved. In addition, the combining failure rate may vary over time, and the Duty determined with the combining failure rate may not be maintained for a long period of time. In such a case, condition search may be required due to necessity of changing the once-set Duty. Therefore, there has been a demand for a Duty control method that stably maintains the EUV energy stability 30 for a long period of time.

### 3. First Embodiment

### 3.1 Configuration

The configuration of the EUV light generation system 10A of a first embodiment is similar to the configuration of the EUV light generation system 10 of the comparative example shown in FIG. 4, and therefore description thereof is omitted.

### 3.2 Operation

Operation of the EUV light generation system 10A of the first embodiment differs from the operation of the EUV light generation system 10 of the comparative example in the DL combining adjustment subroutine and the DL combining control subroutine.

The DL combining adjustment subroutine of the first embodiment controls the Duty using DL passage interval variation σ as an index. Further, the DL combining control subroutine of the first embodiment uses an optimization search algorithm that controls the Duty using the DL passage interval variation σ as an index. The DL passage interval variation σ[ns] is calculated by the following expression 2.

$$DL passage interval variation σ = \sqrt{\frac{1}{n} {\sum }_{i = 1}^{n} {( Ii - Iave )}^{2}} \qquad ( Expression 2 )$$

In expression 2, n is the number of calculated samples, Ii is the i-th DL passage interval, and Iave is the average of the DL passage intervals for the number of calculation samples. Hereinafter, the DL passage interval variation σ is referred to as a DL passage interval σ.

### 3.2.1 Example of DL Combining Adjustment

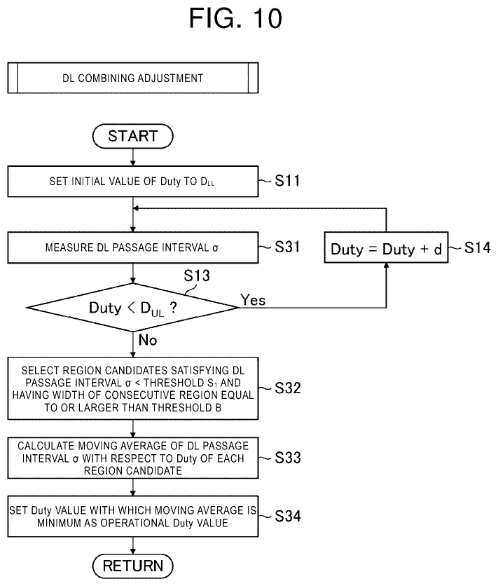

FIG. 10 is a flowchart showing an example of the DL combining adjustment subroutine according to the first embodiment. The subroutine may be performed without EUV light emission, may be performed at the time of EUV light emission, or may be performed continuously regardless of the presence or absence of EUV light emission.

In step S11, the target generation processor 36 sets the Duty for the piezoelectric element 47 to the lower limit value D_{LL} being the initial value. As a typical parameter value of the Duty, the lower limit value D_{LL} may be 18, the upper limit value D_{UL} may be 99%, and the step amount d may be 0.1%.

The target generation processor 36 also acquires the initial parameters. The initial parameters include the number of calculation samples of the DL passage interval σ, the moving average number Nσ of the DL passage interval σ, and the consecutive Duty width determination threshold B. As the typical initial parameters, the number of calculation samples for the DL passage interval σ may be 10000, and the moving average number No of the DL passage interval σ may be 0.6%. When the step amount d is 0.1%, the moving average number Nσ of the DL passage interval σ being 0.6% means that the number of sections of the moving average is 0.6÷0.1=6. The consecutive Duty width determination threshold B may be set by determining a value with which the combining can be maintained for a long period of time by experiment or the like. The consecutive Duty width determination threshold B may be equal to or larger than 0.6%.

In step S31, the target generation processor 36 measures the DL passage interval σ with the set Duty value. That is, the target generation processor 36 controls the piezoelectric power source 37 so as to apply the voltage waveform of the rectangular wave having the set Duty to the piezoelectric element 47, and drives the piezoelectric element 47 via the piezoelectric power source 37 to generate the DL 82. Further, the target generation processor 36 acquires the passage timing signal TS via the EUV light generation processor 24, measures the DL passage interval based on the passage timing signal TS, and calculates the DL passage interval σ based on expression 2. Then, the target generation processor 36 stores the Duty and the DL passage interval σ in association with each other. Here, the target generation processor 36 measures the DL passage interval σ with the conditions other than the Duty being constant.

The process of step S31 is repeated until the Duty value reaches the upper limit value D_{UL}. Thus, by measuring the DL passage interval σ with each Duty value while increasing the Duty from the lower limit value D_{LL} to the upper limit value D_{UL} in increments of the step amount d, characteristic data indicating the relationship between the Duty and the DL passage interval σ can be obtained.

In step S32, the target generation processor 36 acquires region candidates based on the characteristic data acquired in step S31. The region candidates are regions each having a consecutive Duty width with which the DL passage interval σ is smaller than a threshold S₁ and with which the Duty width is equal to or larger than the consecutive Duty width determination threshold B.

In step S33, the target generation processor 36 calculates the moving averages of the DL passage interval σ with respect to the Duty for the respective region candidates selected in step S32. In place of the moving average, the target generation processor 36 may perform filter operation on the data sequence to smooth out protruding data.

In step S34, the target generation processor 36 sets the Duty value with which the moving average calculated in step S33 is the minimum to the operational Duty value.

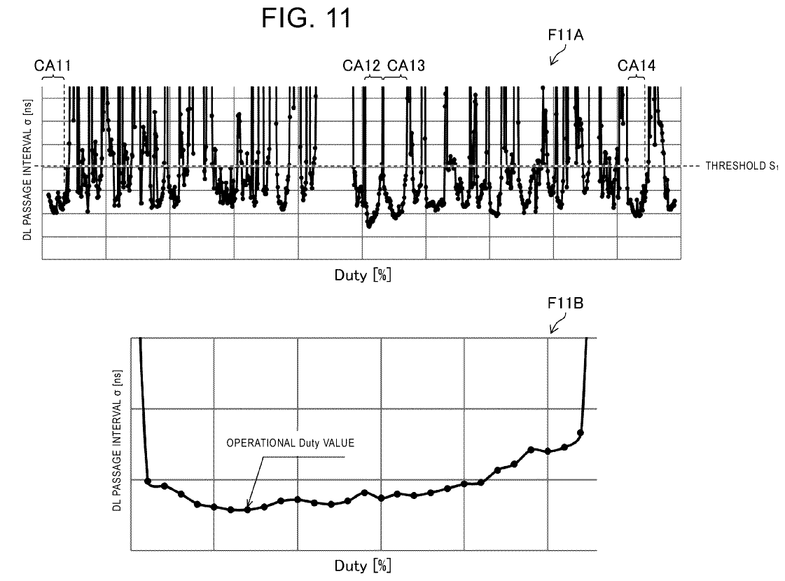

FIG. 11 is a graph showing an example of characteristic data indicating the relationship between the DL passage interval σ and the Duty acquired in the DL combining adjustment. In FIG. 11, the horizontal axis represents the Duty [%], and the vertical axis represents the DL passage interval σ[ns]. F11A of FIG. 11 shows an example of the DL passage interval σ obtained by scanning with the Duty value being from 1% to 99% in increments of 0.1% while the irradiation of the pulse laser light is stopped.

In F11A, four region candidates CA11, CA12, CA13, CA14 are regions satisfying the condition that the consecutive Duty width with which the DL passage interval σ is smaller than the threshold S₁ is equal to or larger than the consecutive Duty width determination threshold B. The region candidates CA11, CA12, CA13, CA14 are regions in the vicinity of the Duty values of 3%, 53%, 56%, and 93%, respectively.

Here, the moving average of the DL passage interval σ with the Duty is calculated for each of the four region candidates CA11, CA12, CA13, CA14, and the operational Duty value is set to the Duty vale with which the moving average is the minimum. F11B of FIG. 11 is an enlarged graph of the region candidate CA12, and shows the set operational Duty value.

### 3.2.2 Example of DL Combining Control

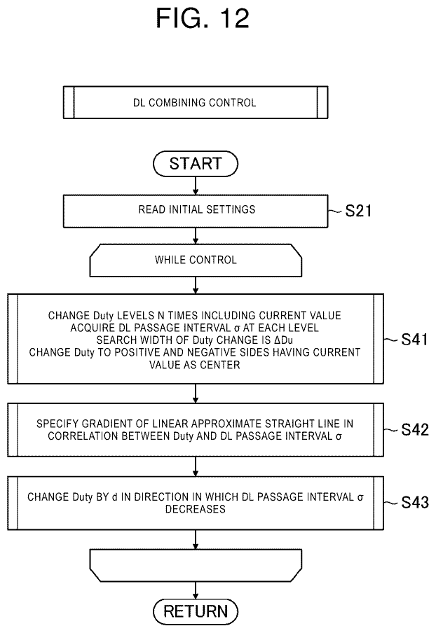

FIG. 12 is a flowchart showing an example of the DL combining control subroutine according to the first embodiment. In the DL combining control subroutine of the first embodiment, the Duty is controlled using the DL passage interval σ as an index. This subroutine can be performed at both the time of EUV light non-emission and the time of EUV light emission. The Duty is an example of the “vibration parameter” in the present disclosure.

In step S21, the target generation processor 36 reads initial settings. The parameters to be initialized include the search width ΔDu of the Duty value for evaluating EUV performance, the search levels N of the Duty, the Duty moving amount d, and the number of calculation samples of the DL passage interval σ. The target generation processor 36 reads the initial set values for each of these parameters. The search width ΔDu may be 0.02%, the search levels N may preferably be 2 or more, for example, 5, the Duty moving amount d may be 0.02%, and the number of calculation samples of the DL passage interval σ may be 10000.

The processes of steps S41 to S43 are for maintaining the DL combining state by finely adjusting the Duty value using the DL passage interval σ as an index, and are performed repeatedly as long as the combining state of the DL needs to be maintained. When there is no need to maintain the DL combining state in association with the stop of DL outputting by the stop command or the like from an external apparatus such as an exposure apparatus (not shown) or an operator, the target generation processor 36 ends the repetitive processes and ends the present subroutine. In step S41, the target generation processor 36 drives the piezoelectric element 47 with the Duty values of the search levels N having the current value of the Duty as the center based on the initial settings read in step S21 to generate the DL. Further, the target generation processor 36 acquires the DL passage interval σ for the generated DL and obtains a correlation between the Duty and the DL passage interval σ. The interval between the search levels N is the search width ΔDu, and the order of the Duty value for acquiring the DL passage intervals σ may be arbitrary. In addition, it is desirable that the search range be set to a range in which a significant difference in DL combining performance is obtained. The current value of the Duty is an example of the “first value” in the present disclosure. The current value of the first Duty in the DL combining control may be the operational Duty determined through the DL combining adjustment. The Duty values of the search levels N having the current value of the Duty as the center is the “plurality of values including the first value” in the present disclosure.

In step S42, the target generation processor 36 calculates a linear approximate straight line with the Duty as the horizontal axis and the DL passage interval σ as the vertical axis in the correlation between the Duty and the DL passage interval σ acquired in step S41, and specifies the gradient thereof.

In step S43, the target generation processor 36 changes the Duty in the performance improving direction, that is, in the direction in which the DL passage interval σ decreases, based on the gradient of the approximate straight line specified in step S42. For example, when the gradient is positive, the target generation processor 36 changes the Duty from the current value (0 position) to the negative direction. Further, when the gradient is negative, the target generation processor 36 changes the Duty from the current value to the positive direction. The change of the Duty at this time may be set to a Duty value that differs from the current value by the moving amount d, or a Duty value that is in the performance improving direction. The change amount in the Duty may be different depending on the value of the gradient. Thereafter, the piezoelectric element 47 is driven with the Duty value having the smaller DL passage interval σ. The changed Duty value is an example of the “second value” in the present disclosure. Here, when the absolute value of the gradient can be regarded as 0, the target generation processor 36 may not change the Duty.

The target generation processor 36 returns to step S41 and repeats the same processes with the changed Duty as the current value.

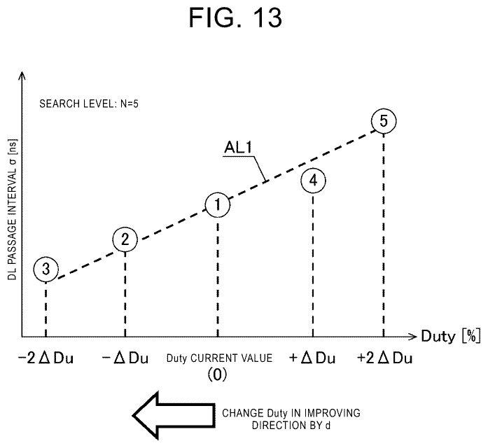

FIG. 13 is a graph for explaining the process of changing the Duty in the performance improving direction. In FIG. 13, the horizontal axis represents the Duty, and the vertical axis represents the DL passage interval σ. Each circle in FIG. 13 represents a plot position of the DL passage interval σ with respect to the Duty, and a number in the circle represents a search order. In the example shown in FIG. 13, the Duty values of the search orders 1, 2, 3, 4, and 5 are “current value”, “current value−ΔDu”, “current value−ΔDu×2”, “current value+ΔDu”, and “current value+ΔDu×2”, respectively. From these five plot points, an approximate straight line AL1 indicated by a broken line in FIG. 13 can be obtained by linear approximation.

In the example of FIG. 13, a gradient S of the approximate straight line AL1 is larger than 0, and the direction in which the Duty is decreased with respect to the current value is the direction in which the value of the DL passage distance σ is improved. Therefore, in this case, as the process of step S43, the Duty value is changed from the current value to the negative direction by the moving amount d.

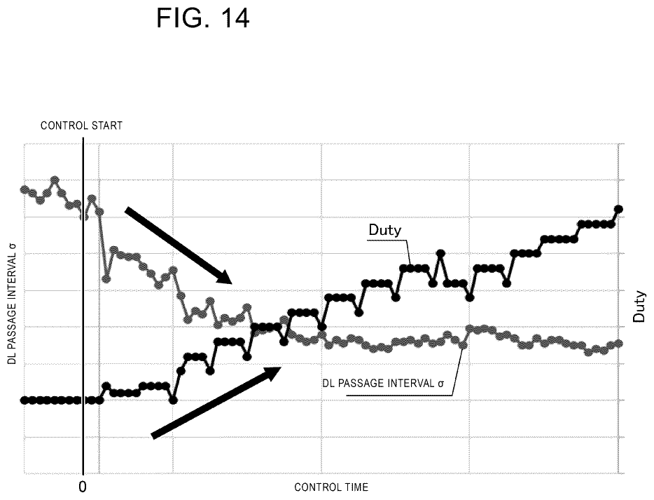

FIG. 14 is a graph showing an example of change in the DL passage interval σ and the Duty with respect to the control time in the DL combining control according to the first embodiment. In this example, the DL passage interval σ is improved by being controlled so as to increase the Duty value in a broad sense.

### 3.3 Effect

According to the EUV light generation system 10A of the first embodiment, the Duty for the piezoelectric element 47 can be optimized and the DL passage interval σ can be reduced even when the combining failure rate is equal to or lower than the threshold.

Even when there is a change with time in the piezoelectric element 47 and the like, the relative irradiation position between the DL and the laser light is stabilized, the EUV energy stability (for example, 3 σ) is improved, and the generation of fragments is suppressed. Further, the EUV light emission cycle is stabilized.

Further, according to the EUV light generation system 10A of the first embodiment, since the Duty value with which the moving average of the DL passage interval σ is the minimum is selected from the excellent Duty region, even if there is some disturbance, the DL passage interval σ does not deteriorate significantly, and the duty value once set can be maintained for a relatively long period of time.

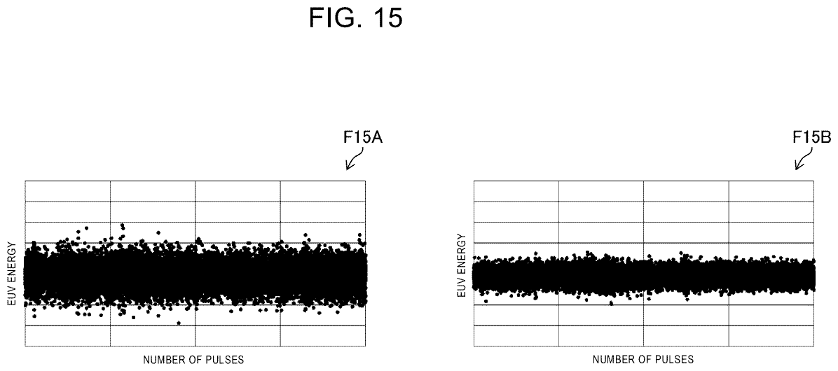

FIG. 15 is a graph showing correlations between the DL passage interval σ and the EUV performance. In FIG. 15, the horizontal axis represents the number of pulses of the generated EUV light, and the vertical axis represents the EUV energy. F15A of FIG. 15 shows the case of the EUV light generation system 10 according to the comparative example, and F15B shows the case of the EUV light generation system 10A according to the first embodiment, and the numbers of pulses are the same. As shown in FIG. 15, the EUV light generation system 10A using the DL passage interval σ as an index provide the EUV energy being more stable and having less variation.

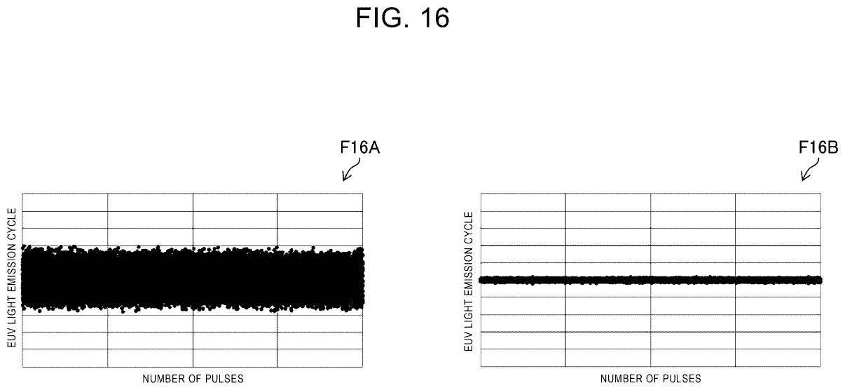

FIG. 16 is a graph showing correlations between the DL passage interval σ and the EUV light emission cycle. In FIG. 16, the horizontal axis represents the number of pulses of the generated EUV light, and the vertical axis represents the EUV light emission cycle. F16A of FIG. 16 shows the case of the EUV light generation system 10 according to the comparative example, and F16B shows the case of the EUV light generation system 10A according to the first embodiment, and the numbers of pulses are the same. As shown in FIG. 16, the EUV light generation system 10A using the DL passage interval σ as an index provide the EUV light emission cycle being more stable and having less variation.

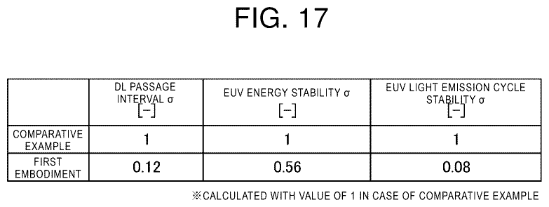

FIG. 17 is a table showing the relationship among the DL passage interval σ, the EUV energy stability, and the EUV light emission cycle stability in numerical values. Here, each index of the EUV light generation system 10A according to the first embodiment is normalized with a value of 1 in the case of the EUV light generation system 10 according to the comparative example. As shown in FIG. 17, the DL passage interval σ of the first embodiment is 0.12, and the EUV energy stability and the EUV light emission cycle stability are 0.56 and 0.08, respectively.

As described above, if the DL passage interval σ can be kept small, the EUV energy stability and the EUV light emission interval can be maintained satisfactorily. This is because the relative position between the DL and the laser light is stabilized when the DL passage interval σ is kept small.

### 3.4 Modification

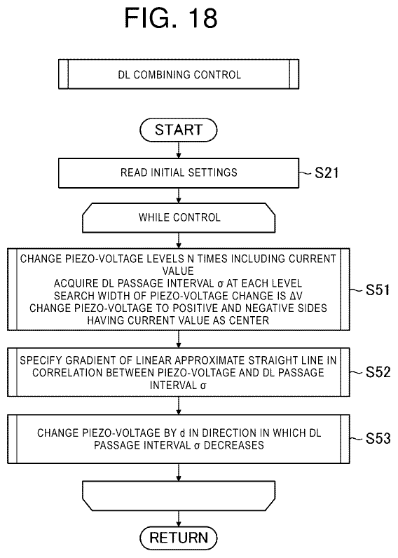

FIG. 18 is a flowchart showing an example of the DL combining control subroutine according of a modification of the first embodiment.

In the modification of the first embodiment, instead of the Duty in the first embodiment, a piezo-voltage which is a voltage for driving the piezoelectric element 47 is controlled. The piezo-voltage may be a voltage amplitude of a rectangular wave applied to the piezoelectric element 47. The Duty may be fixed to the operational Duty value determined through the DL combining adjustment. The piezo-voltage is an example of the “vibration parameter” in the present disclosure.

In step S21, the target generation processor 36 reads the initial settings. As the parameters to be initialized, a search width ΔV may be 0.6 V, the search levels N may be 3, and the improvement amount d of the piezo-voltage may be 0.6 V. The initial value of the piezo-voltage may be determined in advance by an experiment or the like, and a typical value may be selected from past operation data.

The processes of steps S51 to S53 are processes to be repeated. In step S51, the target generation processor 36 acquires the DL passage intervals σ at the piezo-voltages of the search levels N having the current value, which is the currently set piezo-voltage, as the center and obtains the correlation between the piezo-voltage and the DL passage interval σ. The interval between the search levels N is the search width ΔV, and the order of the piezo-voltages for acquiring the DL passage intervals σ may be arbitrary. The current value of the piezo-voltage is an example of the “first value” in the present disclosure.

In step S52, the target generation processor 36 calculates a linear approximate straight line with the piezo-voltage as the horizontal axis and the DL passage interval σ as the vertical axis in the correlation between the piezo-voltage and the DL passage interval σ acquired in step S51, and specifies the gradient thereof.

In step S53, the target generation processor 36 changes the piezo-voltage by d in the performance improving direction based on the gradient of the approximate straight line specified in step S52. The piezo-voltage after the change is an example of the “second value” in the present disclosure. The target generation processor 36 returns to step S51 and repeats the same processes with the changed piezo-voltage as the current value.

### 4. Second Embodiment

### 4.1 Configuration

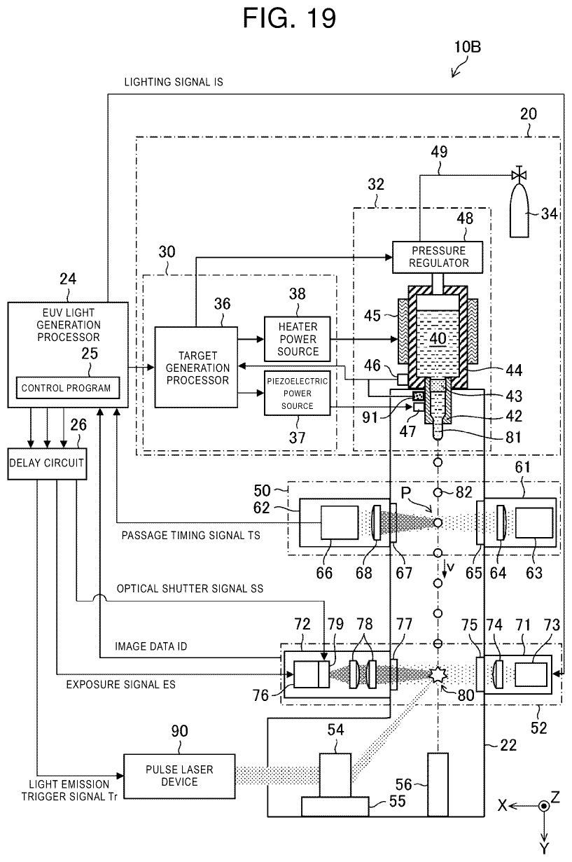

FIG. 19 is a diagram schematically showing an exemplary configuration of an EUV light generation system 10B according to a second embodiment. The EUV light generation system 10B includes a temperature sensor 91 that measures the temperature of the piezoelectric element 47. The temperature sensor 91 may be fixed to the piezoelectric element 47. The EUV light generation system 10B may include a temperature adjustment unit that adjusts the temperature of the piezoelectric element 47.

### 4.2 Operation

Operation of the EUV light generation system 10B of the second embodiment differs from the operation of the EUV light generation system 10A of the first embodiment only in the DL combining control subroutine. That is, in the second embodiment, as in the first embodiment, the DL combining adjustment is performed prior to the DL combining control to adjust the Duty to the optimum operational Duty value.

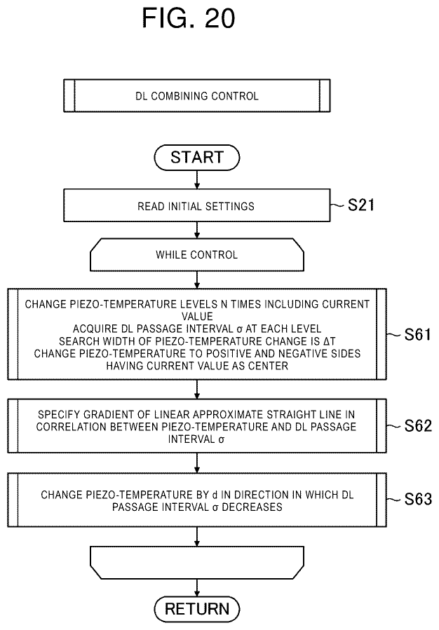

FIG. 20 is a flowchart showing an example of the DL combining control subroutine according to the second embodiment. In the DL combining control of the second embodiment, instead of the Duty in the DL combining control of the first embodiment, the piezo-temperature which is the temperature of the piezoelectric element 47 is controlled. The Duty may be fixed to the operational Duty value determined through the DL combining adjustment. The piezo-temperature is an example of the “vibration parameter.”

In step S21, the target generation processor 36 reads the initial settings. As the parameters to be initialized, a search width ΔT may be 0.2° C., the search levels N may be 3, and the improvement amount d of the piezo-temperature may be 0.2° C. The initial value of the piezo-temperature may be determined in advance by an experiment or the like, and a typical value may be selected from past operation data.

The processes of steps S61 to S63 are processes to be repeated. In step S61, the target generation processor 36 acquires the DL passage intervals σ at the piezo-temperatures of the search levels N having the current value, which is the currently set piezo-temperature, as the center and obtains the correlation between the piezo-temperature and the DL passage interval σ. The interval between the search levels N is the search width ΔT, and the order of the piezo-temperatures for acquiring the DL passage intervals σ may be arbitrary. The current value of the piezo-temperature is an example of the “first value” in the present disclosure.

In step S62, the target generation processor 36 calculates a linear approximate straight line with the piezo-temperature as the horizontal axis and the DL passage interval σ as the vertical axis in the correlation between the piezo-temperature and the DL passage interval σ acquired in step S61, and specifies the gradient thereof.

In step S63, the target generation processor 36 changes the piezo-temperature by the improvement amount d in the performance improving direction based on the gradient of the approximate straight line specified in step S62. The piezo-temperature after the change is an example of the “second value” in the present disclosure. The target generation processor 36 returns to step S61 and repeats the same processes with the changed piezo-temperature as the current value.

### 4.3 Effect

According to the EUV light generation system 10B of the second embodiment, the temperature of the piezoelectric element 47 can be optimized and the DL passage interval σ can be reduced. Therefore, the relative irradiation position between the DL and the laser light is stabilized, the EUV energy stability is improved, and the generation of fragments is suppressed. Further, the EUV light emission cycle is stabilized.

### 5. Third Embodiment

### 5.1 Configuration

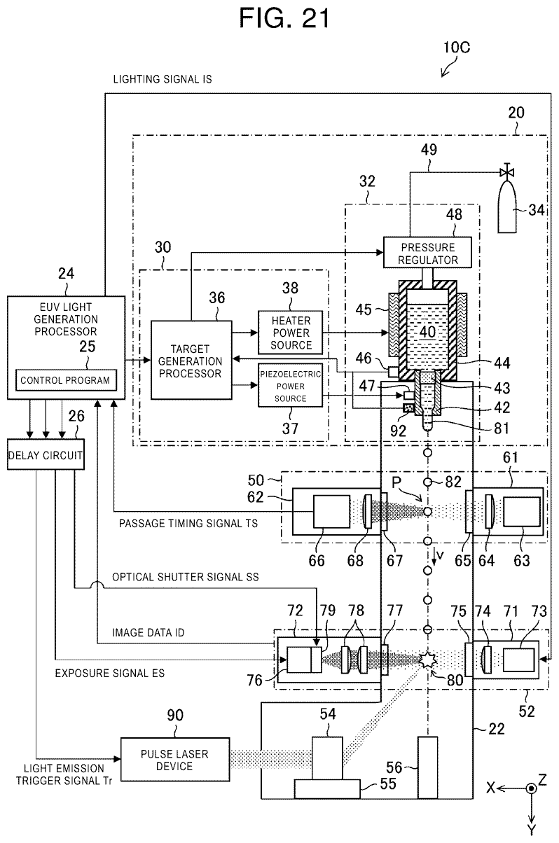

FIG. 21 is a diagram schematically showing an exemplary configuration of an EUV light generation system 10C according to a third embodiment. The EUV light generation system 10C includes a temperature sensor 92 that measures the temperature of the nozzle 42. The temperature sensor 92 may be fixed to the nozzle 42. The EUV light generation system 10C may include a temperature adjustment unit that adjusts the temperature of the nozzle 42.

### 5.2 Operation

Operation of the EUV light generation system 10C according to the third embodiment differs from the operation of the EUV light generation system 10A according to the first embodiment only in the DL combining control subroutine. That is, in the third embodiment, as in the first embodiment, the DL combining adjustment is performed prior to the DL combining control to adjust the Duty to the optimum operational Duty value.

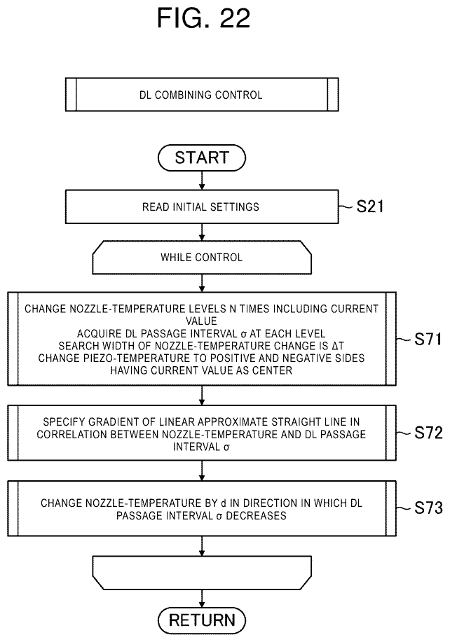

FIG. 22 is a flowchart showing an example of the DL combining control subroutine according to the third embodiment. In the DL combining control of the third embodiment, instead of the Duty in the DL combining control of the first embodiment, the nozzle-temperature which is the temperature of the nozzle 42 is controlled. The Duty may be fixed to the operational Duty value determined through the DL combining adjustment. The nozzle-temperature is an example of the “vibration parameter” in the present disclosure.

In step S21, the target generation processor 36 reads the initial settings. As the parameters to be initialized, a search width ΔTn may be 0.2° C., the search levels N may be 3, and the improvement amount d of the nozzle-temperature may be 0.2° C. The initial value of the nozzle-temperature may be determined in advance by an experiment or the like, and a typical value may be selected from past operation data.

In step S71, the target generation processor 36 acquires the DL passage intervals σ at the nozzle-temperatures of the search levels N having the current value, which is the currently set nozzle-temperature, as the center and obtains the correlation between the nozzle-temperature and the DL passage interval σ. The interval between the search levels N is the search width ΔT, and the order of the nozzle-temperatures for acquiring the DL passage interval σ may be arbitrary. The current value of the nozzle-temperature is an example of the “first value” in the present disclosure.

In step S72, the target generation processor 36 calculates a linear approximate straight line with the nozzle-temperature as the horizontal axis and the DL passage interval σ as the vertical axis in the correlation between the nozzle-temperature obtained in step S71 and the DL passage interval σ, and specifies the gradient thereof.

In step S73, the target generation processor 36 changes the nozzle-temperature by the improvement amount d in the performance improving direction based on the gradient of the approximate straight line specified in step S72. The nozzle-temperature after the change is an example of the “second value” in the present disclosure. The target generation processor 36 returns to step S71 and repeats the same processes with the changed nozzle-temperature as the current value.

### 5.3 Effect

According to the EUV light generation system 10C of the third embodiment, the temperature of the nozzle 42 can be optimized and the DL passage interval σ can be reduced. Therefore, the relative irradiation position between the DL and the laser light is stabilized, the EUV energy stability is improved, and the generation of fragments is suppressed. Further, the EUV light emission cycle is stabilized.

### 6. Electronic Device Manufacturing Method

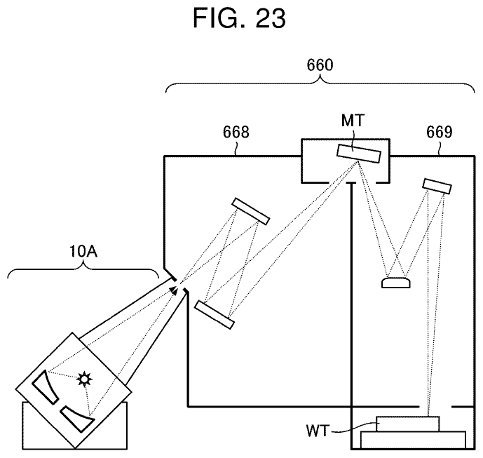

FIG. 23 schematically shows the configuration of an exposure apparatus 660 connected to the EUV light generation system 10A. The exposure apparatus 660 includes a mask irradiation unit 668 and a workpiece irradiation unit 669. The mask irradiation unit 668 illuminates, via a reflection optical system, a reticle pattern of a reticle table MT with EUV light incident from the EUV light generation system 10A. The workpiece irradiation unit 669 images the EUV light reflected by the reticle table MT onto a workpiece (not shown) placed on the workpiece table WT through a reflection optical system. The workpiece is a photosensitive substrate such as a semiconductor wafer on which photoresist is applied.

The exposure apparatus 660 synchronously translates the reticle table MT and the workpiece table WT to expose the workpiece to the EUV light reflecting the reticle pattern. Through the exposure process as described above, a device pattern is transferred onto the semiconductor wafer, thereby an electronic device can be manufactured. The EUV light generation system 10B or the EUV light generation system 10C may be used instead of the EUV light generation system 10A.

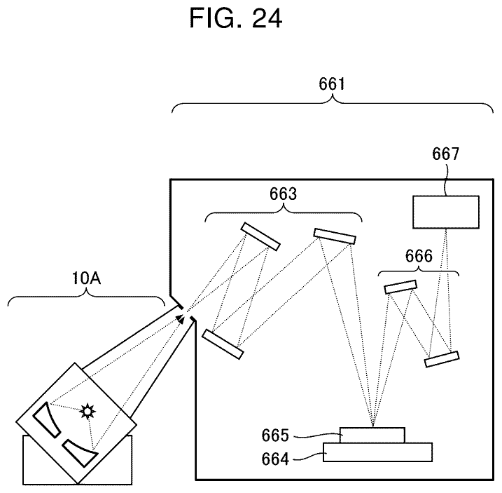

FIG. 24 schematically shows the configuration of an inspection apparatus 661 connected to the EUV light generation system 10A. The inspection apparatus 661 includes an illumination optical system 663 and a detection optical system 666. The illumination optical system 663 reflects the EUV light incident from the EUV light generation system 10A to illuminate a reticle 665 placed on a reticle stage 664. Here, the reticle 665 conceptually includes a mask blanks before a pattern is formed. The detection optical system 666 reflects the EUV light from the illuminated reticle 665 and forms an image on a light receiving surface of a detector 667. The detector 667 having received the EUV light obtains the image of the reticle 665. The detector 667 is, for example, a time delay integration (TDI) camera.

Defects of the reticle 665 are inspected based on the image of the reticle 665 obtained by the above-described inspection process, and a reticle suitable for manufacturing an electronic device is selected using the inspection result. Then, the electronic device can be manufactured by exposing and transferring the pattern formed on the selected reticle onto the photosensitive substrate using the exposure apparatus 660. Also as the configuration shown in FIG. 24, the EUV light generation system 10B or the EUV light generation system 10C may be used instead of the EUV light generation system 10A.

### 7. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system configured to generate extreme ultraviolet light by irradiating a target substance with laser light, comprising:
a tank configured to store the target substance in a liquid state;
a nozzle configured to output the target substance stored in the tank;
a piezoelectric element configured to apply vibration to the target substance to be output from the nozzle to generate droplets of the target substance;
a droplet detection device configured to detect a time interval of passage of the droplets output from the nozzle; and
at least one processor,
the processor acquiring a first value of a vibration parameter relating to the vibration of the piezoelectric element, acquiring a variation of the time interval corresponding to each of a plurality of values including the first value of the vibration parameter, and generating the droplets using a second value with which the variation of the time interval is smaller than that with the first value.

2. The extreme ultraviolet light generation system according to claim 1,
wherein the processor acquires a variation of the time interval corresponding to each of the first value of the vibration parameter, a value larger than the first value, and a value smaller than the first value.

3. The extreme ultraviolet light generation system according to claim 1,
wherein the processor calculates an approximate straight line in correlation between a value of the vibration parameter and the variation of the time interval, and causes the second value to be a value of the vibration parameter providing a smaller variation of the time interval than the first value based on a gradient of the approximate straight line.

4. The extreme ultraviolet light generation system according to claim 1,
wherein the vibration parameter is a duty of a voltage waveform of a rectangular wave for driving the piezoelectric element.

5. The extreme ultraviolet light generation system according to claim 1,
wherein the vibration parameter is a voltage for driving the piezoelectric element.

6. The extreme ultraviolet light generation system according to claim 1,
wherein the vibration parameter is a temperature of the piezoelectric element.

7. The extreme ultraviolet light generation system according to claim 1,
wherein the vibration parameter is a temperature of the nozzle.

8. The extreme ultraviolet light generation system according to claim 1,
wherein the processor generates the droplets by driving the piezoelectric element with a voltage waveform of a rectangular wave having a value of an operational duty, and generates the extreme ultraviolet light by irradiating the droplets with the laser light.

9. The extreme ultraviolet light generation system according to claim 8,
wherein the processor acquires correlation between a duty of the rectangular wave and the variation of the time interval, and causes the value of the operational duty to be a value of the duty with which the variation of the time interval is smallest.

10. The extreme ultraviolet light generation system according to claim 9,
wherein the processor causes the value of the operational duty to be the second value.

11. The extreme ultraviolet light generation system according to claim 1,
wherein the target substance is a liquid target substance containing tin.

12. The extreme ultraviolet light generation system according to claim 11,
wherein the processor melts the tin at a predetermined temperature in a target supply unit including the tank.

13. The extreme ultraviolet light generation system according to claim 11,
wherein the processor controls a pressure of an inert gas to be supplied to the tank by a pressure regulator, and outputs outside liquid tin in the tank from the nozzle.

14. The extreme ultraviolet light generation system according to claim 1,
wherein the piezoelectric element generates the droplets by being driven with the second value of the vibration parameter.

15. The extreme ultraviolet light generation system according to claim 1,
wherein the piezoelectric element is driven by a rectangular wave having a duty value with which the variation of the time interval is smaller than a threshold.

16. The extreme ultraviolet light generation system according to claim 1,
wherein control of maintaining a combining state of the droplets is performed by finely adjusting a duty value for the piezoelectric element.

17. The extreme ultraviolet light generation system according to claim 1,
wherein energy stability of the extreme ultraviolet light is improved by keeping the variation of the time interval small.

18. The extreme ultraviolet light generation system according to claim 1,
wherein a combining state of the droplets is controlled using the variation of the time interval as an index.

19. An electronic device manufacturing method, comprising:
generating extreme ultraviolet light using an extreme ultraviolet light generation system by irradiating a target substance with laser light;
outputting the extreme ultraviolet light to an exposure apparatus; and
exposing a photosensitive substrate to the extreme ultraviolet light in the exposure apparatus to manufacture an electronic device,
the extreme ultraviolet light generation system including:
a tank configured to store the target substance in a liquid state;
a nozzle configured to output the target substance stored in the tank;
a piezoelectric element configured to apply vibration to the target substance to be output from the nozzle to generate droplets of the target substance;
a droplet detection device configured to detect a time interval of passage of the droplets output from the nozzle; and
at least one processor,
the processor acquiring a first value as a vibration parameter relating to vibration of the piezoelectric element, acquiring a variation of the time interval corresponding to each of a plurality of values including the first value as the vibration parameter, and generating the droplets using a second value with which the variation of the time interval is smaller than that with the first value.

20. An electronic device manufacturing method, comprising:
generating extreme ultraviolet light using an extreme ultraviolet light generation system by irradiating a target substance with laser light;
inspecting a defect of a reticle by irradiating the reticle with the extreme ultraviolet light;
selecting a reticle using a result of the inspection; and
exposing and transferring a pattern formed on the selected reticle onto a photosensitive substrate, the extreme ultraviolet light generation system including:
a tank configured to store the target substance in a liquid state;
a nozzle configured to output the target substance stored in the tank;
a piezoelectric element configured to apply vibration to the target substance to be output from the nozzle to generate droplets of the target substance;
a droplet detection device configured to detect a time interval of passage of the droplets output from the nozzle; and
at least one processor,
the processor acquiring a first value as a vibration parameter relating to vibration of the piezoelectric element, acquiring a variation of the time interval corresponding to each of a plurality of values including the first value as the vibration parameter, and generating the droplets using a second value with which the variation of the time interval is smaller than that with the first value.
